(19) United States
(12) Patent Application Publication
(10) Pub. No.: US 2005/0030040 A1
(43) Pub. Date: Feb. 10, 2005

(54) Electrical testing device having voice annunciator

(76) Inventors: Mitch Budniak, Highland Park, IL (US); Kerry Berland, Chicago, IL (US); Paul Berland, Elgin, IL (US)

Correspondence Address: SONNENSCHEIN NATH & ROSENTHAL LLP, Wacker Drive Station, Sears Tower, P.O. Box 061080, Chicago, IL, 60606-1080, US

(21) Appl. No.: 10/879,546

(22) Filed: Jun. 28, 2004

Related U.S. Application Data
(60) Provisional application No. 60/482,920, filed on Jun. 27, 2003.

(51) Int. Cl. G01R 31/02

(52) U.S. Cl. 324/403

(57) ABSTRACT

Methods and systems consistent with the present invention provide for annunciating a measured electrical value. A handheld electrical tester measures an electrical characteristic. A processor determines one or more spoken words corresponding to a value of the measured electrical characteristic. The one or more spoken words are annunciated via a speaker.

### STATEMENT OF RELATED APPLICATIONS

This application is based on U.S. Provisional Application Ser. No. 60/482,920 filed Jun. 27, 2003. This application claims priority to the filing date of the above-identified patent application, which is incorporated herein by reference to the extent permitted by law.

### BACKGROUND OF THE INVENTION

The present invention generally relates to the field of electrical testing devices and, more particularly, to an electrical testing device having a voice annunciator.

Typical electrical testing devices, such as voltmeters and conductivity meters, have display devices for displaying a measured value. For example, a conventional voltmeter may have a liquid crystal display (LCD) that displays a measured voltage value. In another example, an electrical tester may have a vibrating device that vibrates when, for example, a voltage is detected. While this second example is helpful to indicate the presence of a voltage when a user cannot see the display, it fails to provide the user with the voltage's measured value.

To measure an electrical characteristic, a user typically contacts one or more of the electrical tester's probes to one or more measurement points. When a measurement point is within an enclosure or in a low-light environment, it can be difficult for the user of an electrical tester to focus simultaneously on the electrical tester display and on probes. It is therefore typically difficult to use an electrical tester in such environments.

### SUMMARY OF THE INVENTION

Methods and systems consistent with the present invention provide a handheld electrical testing device that can annunciate measured values. The electrical testing device can measure various electrical characteristics, such as alternating current (AC) voltage, direct current (DC) voltage, conductivity, and other characteristics. A processor in the electrical testing device retrieves spoken word information, for each numerical value and word value corresponding to the measured characteristic, and annunciates the spoken word information via a speaker.

In an illustrative example, the electrical testing device measures a voltage potential of 119 volts AC. The processor retrieves spoken word information for “119,” the word “VOLTS,” and the word “AC.” The processor annunciates each of the these items of spoken word information via a speech synthesizing chip and a speaker. The word information is preferably stored in an EEPROM. Therefore, different language sets can be installed without affecting the processor's program.

Therefore, unlike conventional electrical testers, which merely provide a read-out display or a vibration, methods and systems consistent with the present invention provide an electrical tester having a voice annunciator. Accordingly, when there is a low-light condition or if a user cannot watch or otherwise see the electrical tester's display device, the user can still hear the measured value via the electrical tester's voice annunciator.

In accordance with methods consistent with the present invention, a method in a handheld electrical tester having a program is provided. The method comprises the steps of measuring a measurement data having a value; determining one or more spoken words corresponding to the measured data's value; and annunciating the measurement data's value.

In accordance with systems consistent with the present invention, a handheld electrical tester is provided. The handheld electrical tester comprises: a memory having a program that measures a measured data having a value, determines one or more spoken words corresponding to the measured data's value, and annunciates the one or more spoken words; and a processor that runs the program.

In accordance with systems consistent with the present invention, a handheld electrical tester is provided. The handheld electrical tester comprises: a sensor that measures a voltage potential; a processor that determines one or more spoken words corresponding to a value of the measured voltage potential; and a speaker that annunciates the one or more spoken words.

In accordance with systems consistent with the present invention, a handheld electrical tester is provided. The handheld electrical tester comprises: a memory having a program that measures a measured data having a value, determines one or more audible sounds corresponding to the measured data's value, and annunciates the one or more audible sounds; and a processor that runs the program.

Other features of the invention will become apparent to one with skill in the art upon examination of the following figures and detailed description. It is intended that all such additional systems, methods, features and advantages be included within this description, be within the scope of the invention, and be protected by the accompanying drawings.

### BRIEF DESCRIPTION OF THE DRAWINGS

The accompanying drawings, which are incorporated in and constitute a part of this specification, illustrate an implementation of the invention and, together with the description, serve to explain the advantages and principles of the invention. In the drawings,

FIG. 1 is a schematic diagram of an electrical tester consistent with the present invention measuring an electrical characteristic of a circuit;

FIGS. 2A-2H are block diagrams of the electrical testing device of FIG. 1;

FIG. 3 is a flow diagram of the exemplary steps performed by the program consistent with the present invention;

FIG. 4 is a flow diagram of the exemplary steps performed by the program for processing a low-battery condition;

FIG. 5 is a flow diagram of the exemplary steps performed by the program for processing an automatic power-off;

FIG. 6 is a flow diagram of the exemplary steps performed by the program for processing an inputted non-contact voltage sense; and

FIG. 7 is a flow diagram of the exemplary steps performed by the program for processing an inputted probe signal.

### DETAILED DESCRIPTION OF THE INVENTION

Reference will now be made in detail to an implementation in accordance with methods, systems, and articles of manufacture consistent with the present invention as illustrated in the accompanying drawings. Wherever possible, the same reference numbers will be used throughout the drawings and the following description to refer to the same or like parts.

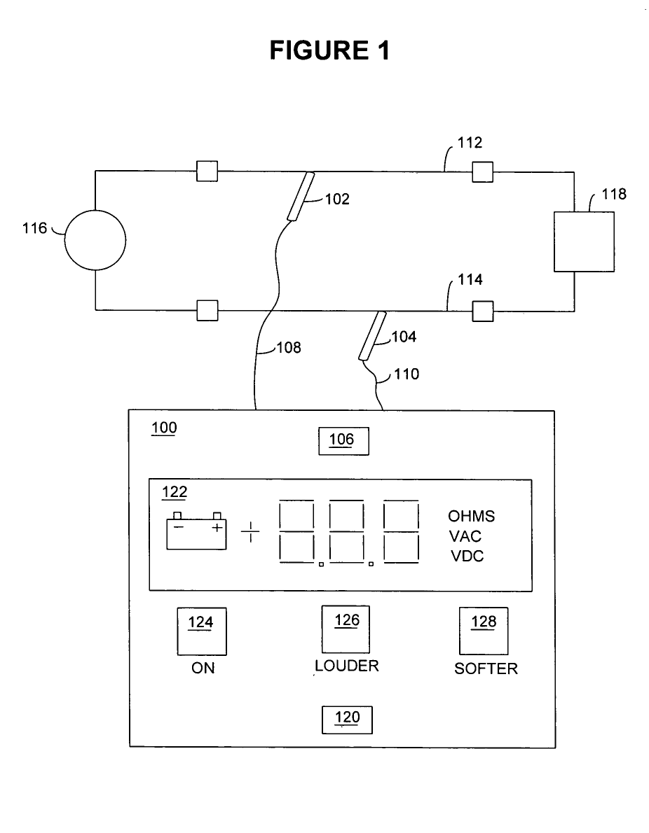

Methods and systems consistent with the present invention provide a handheld electrical testing device that can measure electrical characteristic data and annunciate the measured values. FIG. 1 depicts a block diagram of an illustrative testing device 100 consistent with the present invention. In the illustrative example, testing device 100 can be a handheld device that can measure and annunciate values for one or more electrical characteristics, such as alternating current voltage, direct current voltage and conductivity. However, testing device 100 can alternatively measure other characteristics and annunciate those other measured values, such as, for example, current, impedance, or temperature.

The illustrative testing device 100 can obtain measurement information either using a first probe 102 and a second probe 104, or using a non-contact sensor 106. First probe 102 connects to testing device 100 via a first lead 108. Second probe 104 connects to testing device 100 via a second lead 110. As shown, first probe 102 can be contacted to a first measurement point, such as a first wire 112, and second probe 104 can be contacted to a second measurement point, such as a second wire 114, to obtain measurement information. In the illustrative example of FIG. 1, a voltage potential is applied across first wire 112 and second wire 114 via a voltage source 116 to drive a load 118. Testing device 100 can obtain voltage and conductivity information, for example, by contacting first probe 102 to first wire 112 and second probe 104 to second wire 114. Testing device 100 can also obtain measurement information using non-contact sensor 106. Non-contact sensor 106 can detect a voltage potential without the need to make a direct ohmic connection to the measurement point. First probe 102, second probe 104, and non-contact sensor 106 will be described in more detail below.

Testing device 100 includes an annunciator 120 that annunciates values of measurement information obtained by testing device 100. For example, if testing device 100 measures a voltage potential of 100 VAC across first wire 112 and second wire 114, annunciator 120 can annuciate the value “120 volts” in a desired language. The measured value is also displayed on a display 122, which is for example a liquid crystal display device.

A user can power-on and power-off testing device 100 using a power actuator 124. The user can also increase the volume of annunciator 120 using a volume increase actuator 126 and can decrease the volume of the annunciator 120 using a volume decrease actuator 128. In the illustrative example, the actuators are buttons, however, one having skill in the art can appreciates that alternative actuators can be used, such as dials, switches or touch-panel inputs. Further, testing device 100 can include additional or alternative input and output devices. For example, testing device 100 can include one or more actuators for selecting a particular type of information to measure, such as temperature, current, voltage, or conductivity. Probes suitable for obtaining the respective measurement information can also be provided, such as temperature sensors.

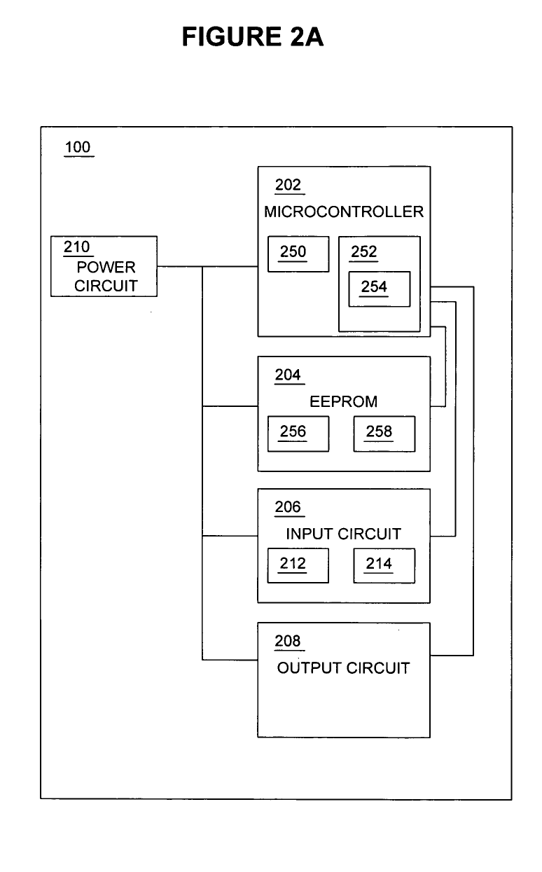

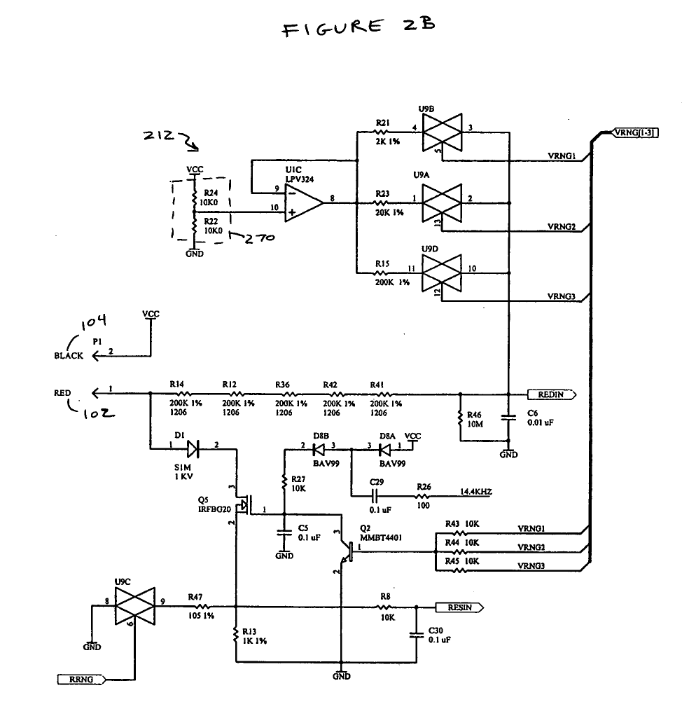

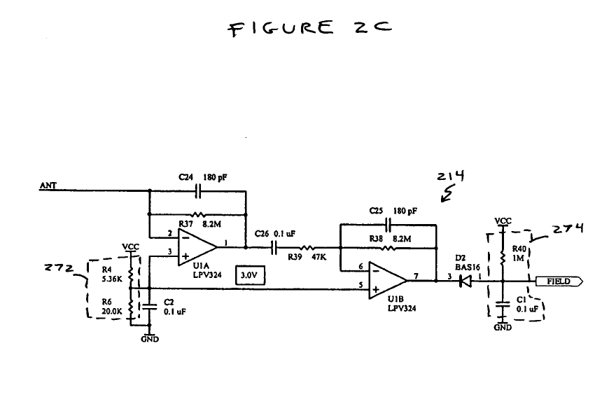

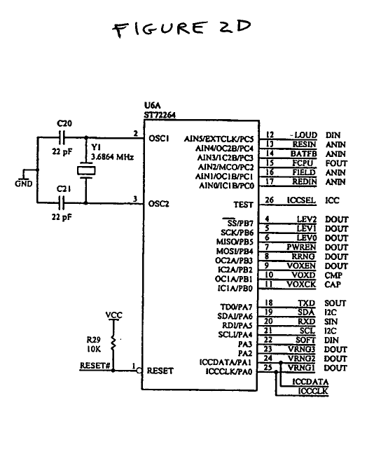

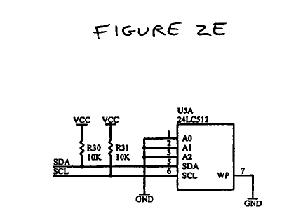

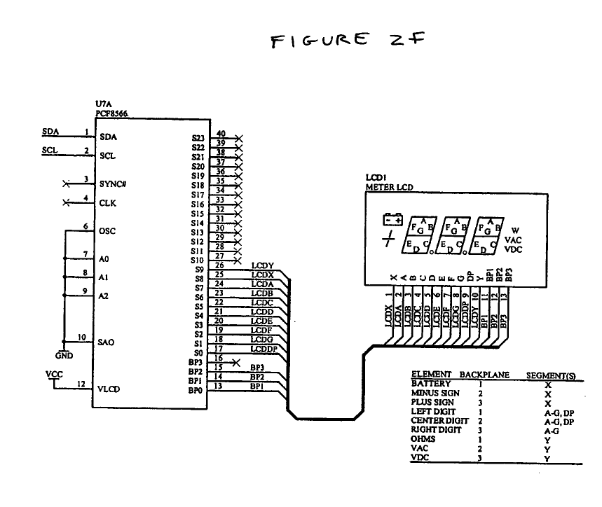

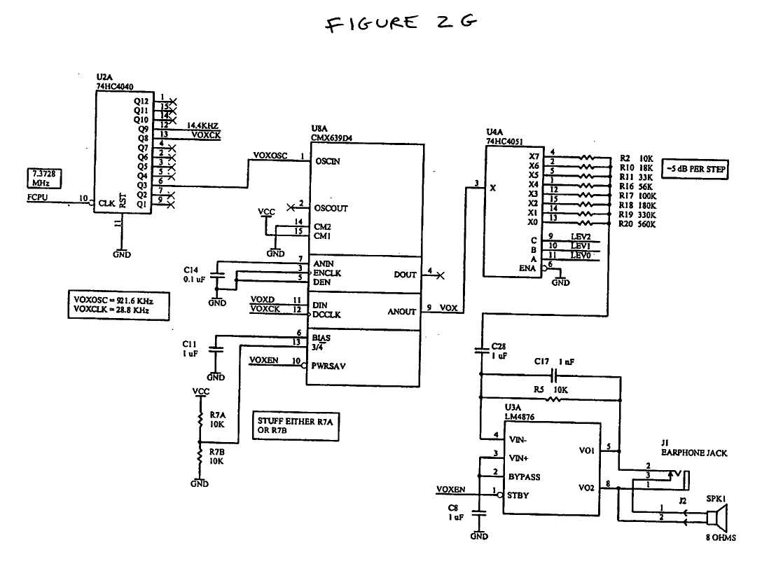

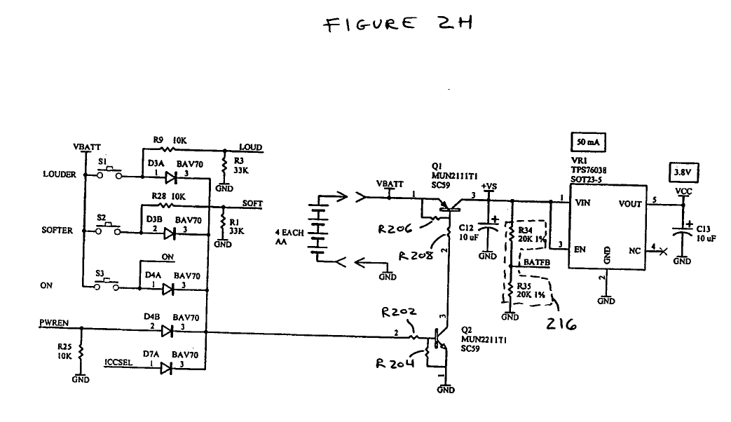

FIG. 2A depicts a schematic block diagram of testing device 100's illustrative electronics. As shown, the illustrative testing device 100 includes a microcontroller 202, a memory circuit 204, an input circuit 206, an output circuit 208, and a power circuit 210. Input circuit 206 includes a probe input circuit 212 and a field detector circuit 214. Each of these components will be described in more detail below.

FIG. 2B depicts probe input circuit 212 in more detail. The electrical tester can auto-range among two or more voltage and resistance ranges. In the illustrative example, the electrical tester can auto-range among the three voltage ranges shown below in Table 1. Further, the electrical tester can auto-range among the two resistance ranges 0.0 through 99.9 and 100 through 999.

In the illustrative example, probe input circuit 212 can receive input signals from a first probe 102 and a second probe 104. As shown, probe 104 is coupled to a reference voltage Vcc of 3.8 volts, which is supplied from power circuit 210. Probe 102 receives a signal from the measurement point at which it contacts. The measured signal is received by the microcontroller as voltage signal REDIN. The program in the microcontroller determines in which of the three voltage ranges the voltage signal REDIN falls. If the voltage is within the first illustrative range then the microcontroller outputs voltage range signal VRNG1, if the voltage is within the second illustrative range then the microcontroller outputs voltage range signal VRNG2, and if the voltage is within the third illustrative range then the microcontroller outputs voltage range signal VRNG3.

One of the voltage range signals is supplied to one of the quad switches U9A, U9B or U9D to enable the respective quad switch. As shown in FIG. 2B, reference voltage Vcc is divided in half by a voltage divider 270 comprising resistor 24 and resistor 22. The divided voltage is supplied to the non-inverting input of operational amplifier U1C. Depending on which voltage range signal is a high signal, one of the quad switches U9B, U9A or U9D is enabled to receive and pass the output signal from operational amplifer U1C. A resistor R21, R23 or R15 corresponding to the quad switch acts as part of a voltage divider to regulate the voltage signal REDIN.

If the voltage signal REDIN drifts, the microcontroller may switch to a different voltage range signal to accommodate the voltage signal REDIN being within a new voltage range. Thus, the microcontroller auto-ranges the voltage signal.

If the voltage signal REDIN is less than the lowest range (i.e., less than 0.5 volts), the program determines that it is measuring and analyzing resistance instead of voltage. If the voltage signal REDIN does not fall within the three predetermined ranges, then the microcontroller does not output voltage range signals VRNG1, VRNG2 and VRNG3. Accordingly, transistor Q2 turns off, which turns transistor Q5 on. A signal received from probe 102 will pass through diode D1 and transistor Q5, and will pass via resistor R8 to the microcontroller as resistance signal RESIN. Thus, the microcontroller automatically switches from voltage sensing mode to resistance sensing mode and vice-versa depending on the state of transistor Q2.

When the resistance signal RESIN is received by the microcontroller, the program in the microcontroller determines in which of the two illustrative resistance ranges the resistance signal RESIN falls. If the resistance is within the second illustrative range then the microcontroller outputs resistance range signal RRNG. Resistance range signal RRNG is supplied to a quad switch U9C to enable the quad switch to regulate the resistance range via resistors R47 and R13. Accordingly, the microcontroller can also auto-range the resistance.

In addition to obtaining voltage measurements via first probe 102 and second probe 104, electrical tester 100 further detects 60 Hz signals using field detector circuit 214, which is shown in more detail in FIG. 2C. When the user brings electrical tester 100 close to an AC line voltage, non-contact sensor 106 acts as an antenna and responds to the 60 Hz voltage signal. Non-contact sensor 106 is preferably a copper foil area on both sides of the electrical tester 100's printed circuit board.

The field detector circuit further includes an operational amplifier U1A. The inverting input circuit of the op amp U1A is a high impedance circuit, which facilitates detection of weak AC fields. The non-inverting input of op amp U1A connects to +3V. The +3V is obtained by applying Vcc to voltage divider 272, which includes resistor R4, resistor R6 and capacitor C2. Since the DC gain of U1 is about unity, the DC output level of U1A is approximately 3 volts. The AC gain preferably has a value, which is determined by resistor R37. Capacitor C24 is intended to remove high frequency noise.

60 Hz signals are further amplified by operational amplifier U1B. Because of the high gain at op amp U1B, C26 is a blocking capacitor that prevents input offset voltage at op amp U1A from being amplified by op amp U1A's gain and resulting in a shift in the DC output at pin 1 of op amp U1A away from the intended 3 volt level. The AC gain of U1B is determined by the ratio of resistor R39 and resistor R38. Capacitor C25 is intended to remove high frequency noise.

Diode D2 connects to the output of op amp U1B. Diode D2's anode terminal connects to an RC filter circuit 274, which includes resistor R40 and capacitor C1. The anode terminal of diode D2 is also connected to analog input channel AN1 of microcontroller U6A. The signal supplied to analog input channel AN1 is labeled “FIELD” for clarity. In the absence of a 60 Hz input signal, microcontroller U6A receives a signal of about 3 volts. When a 60 Hz signal is present, resulting signals are amplified by op amps U1A and U1B, causing the FIELD signal to oscillate around the DC value of 3 volts. During the negative portion of the pulses, diode D2 conducts, momentarily discharging the RC circuit 214. The field detector circuit may similarly be used to detect other frequency signals (e.g., 50 Hz signals) by altering the component values.

Microcontroller U6A in one embodiment is an ST Microcontrollers ST72264 microcontroller, as shown in FIG. 2D. Microcontroller U6A preferably includes a processor 250 and a memory 252, which includes a program 254. The microcontroller's clock is driven by an external oscillator Y1, which is connected to ground via capacitor C20 and capacitor C21. The microcontroller can receive a reset signal RESET#, for example from a microcontroller programmer. As shown, the microcontroller's RESET input is maintained at a high level via resistor R29.

As will be described in more detail below, the program in the microcontroller controls the electrical tester, determines the operating mode, and performs the voltage and resistance measurement tasks. The program remains unchanged regardless of the language used for annunciation. Compressed, digitized voice samples are stored in, for example, an EEPROM USA in the memory circuit 204. The voice samples 256 are downloaded into the EEPROM, for example, during manufacturing. Once the program determines that a message is to be annunciated, the program accesses one or more look-up tables 258 stored in the EEPROM to determine which voice samples to use to generate the appropriate voice message in the applicable language. The program also retrieves the appropriate voice samples from the EEPROM. Data lines SDA and SCL connect the microcontroller to the EEPROM, as shown in FIG. 2E. These data lines are held at a high level via resistor R30 and resistor R31, respectively.

Output circuit 208 includes a liquid crystal display driver U7A and a liquid crystal display LCD1, as shown in FIG. 2F. The microcontroller provides output signals SDA and SCL to liquid crystal display driver U7A, which in turn drives liquid crystal display LCD1. In the illustrative example, the liquid crystal display includes three 7-segment displays, two decimal points, a +/-polarity indicator, a low-battery indicator, an ohm indicator, a VAC indicator, and a VDC indicator.

The output circuit also includes circuitry for annunciation, as shown in FIG. 2G. The annunciation circuit includes a voice chip U8A. In a preferred embodiment, the voice chip U8A is the Consumer Electronics Limited CMX639D4 voice chip. The voice chip receives a word code (i.e., a word such as “VOLT” to be annunciated) from the microcontroller via signal VOXD. However, signal VOXD is transmitted at a different rate than the rate at which the voice chip reconstructs signals. To synchronize the microcontroller with the voice chip so that the word code is reconstructed by the voice chip properly, the microcontroller outputs a clock pulse FCPU to a timer U2A. Timer U2A can output a voice clock signal VOXCK at 28.8 KHz and a voice chip clock signal VOXOSC at 921.6 KHz, each of which are provided to the voice chip. To synchronize the microcontroller with the voice chip, the voice clock signal VOXCK is also provided to pin 11 of the microcontroller. At each rising edge of the voice clock signal VOXCK, the microcontroller shifts out a bit of the word code VOXD, which is received at the voice chip. The voice chip receives the voice clock signal VOXCK at pin 12 of the voice chip, to synchronize to the word code VOXD.

Voice chips and their functionality are known in the art and will not be described in more detail herein. In brief, the illustrative voice chip uses continuously variable-slope delta modulation (CVSD) to reconstruct words contained in the word code VOXD. A description of reconstructing voice signals using CVSD can be found in “MC3417, MC3517, MC3418, MC3518 Specifications and Applications Information”, Motorola, Inc., 1983, which is incorporated herein by reference to the extent permitted by law.

The reconstructed voice signal VOX is output from the voice chip to a gain control U4A. The gain control receives level signals LEV0, LEV1 and LEV2 from microcontroller, which are used by the gain control to select one or more of eight resistors R2, R10, R11, R16, R17, R18, R19, R20 to obtain digitally variable gain control. The output from the gain control is supplied to an audio power amplifier U3A via capacitor C28. Capacitor C17 and resistor R5 provide a feedback loop for the audio power amplifier. The audio power amplifier's output is received by an earphone jack J1 and a speaker SPK1, which annunciate the output.

FIG. 2H shows power circuit 210 in more detail. Power circuit 210 in the illustrative example is driven by four 1.5 volt batteries AA to an input voltage VBATT of 6 volts. The user turns on the electrical tester by pressing the ON, LOUDER or SOFTER button. Once turned on, the electrical tester stays on continuously as long as the first and second probes are connected to an active source of AC or DC voltage, or to a continuity circuit whose resistance is within a continuity measurement range. When the electrical tester has been idle for a period of time, such as fifteen seconds, the electrical tester shuts itself off automatically.

When the ON, LOUDER or SOFTER button is depressed, the respective switch S3, S1 or S2 connects the positive terminal of the battery AA to resistor R202. Transistor Q2 has a pull-down resistor R204, which tends to keep transistor Q2 turned off. Transistor Q2 turns on if resistor R202 is connected to the positive terminal of the battery AA. Transistor Q1 is preferably a PNP transistor whose base connects to resistor R206, tending to keep transistor Q1 off. Transistor Q1 will turn on if transistor Q2 turns on, sinking current through resistor R208. When transistor Q1 turns on, voltage +VS is provided to the input terminal of the voltage regulator VR1. Voltage regulator VR1 outputs an reference voltage Vcc, which is 3.8 volts in the illustrative example.

Shortly after power-up, the microcontroller turns on port pin PWREN to maintain voltage to transistor Q2, which locks the power supply on. As long as port pin PWREN is at a high level, current through resistor R202 keeps transistor Q2 on, which keeps transistor Q1 on.

When the electrical tester has been inactive for a predetermined period of time (i.e., no AC voltage, DC voltage, or continuity circuit is detected), the microcontroller may turn off port pin PWREN to go to sleep and avoid unnecessary battery drain. Transistor Q1 then shuts off, leaving a small leakage current draining from the battery AA. To power-up again, the user depresses one of the buttons.

Further, a resistor divider 216 made up of resistors R34 and R35 measures the battery voltage. The microcontroller's program adjusts the input voltage at BATFP for the voltage drop across transistor Q1. When the potential falls below a preset limit, the microcontroller's program signals a low-battery condition and shuts the electrical tester off.

In addition to being able to power-up the electrical tester, the LOUDER and SOFTER buttons also each provide an input signal to the microcontroller. When the LOUDER button is depressed, the LOUD signal is inputted to the microcontroller. And when the SOFTER button is depressed, the SOFT signal is inputted to the microcontroller.

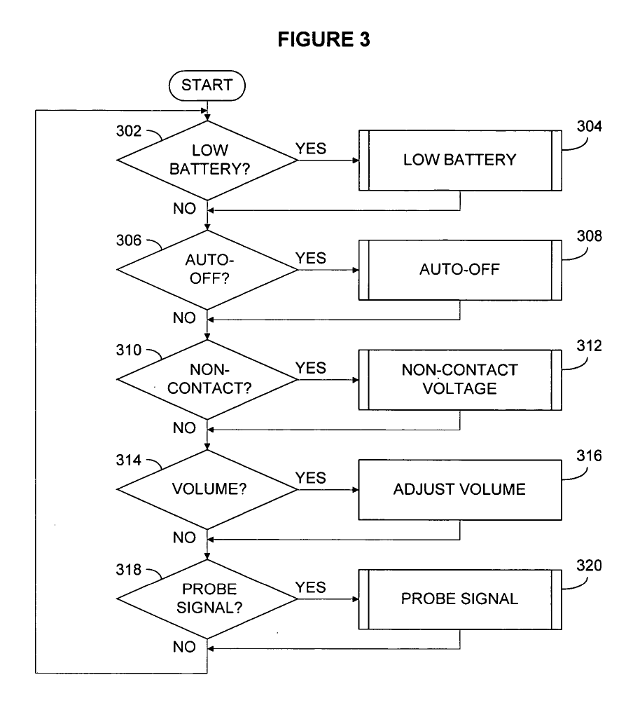

FIG. 3 is a flow chart of the exemplary steps performed by the program in the microcontroller. The program may comprise or may be included in one or more code sections containing instructions for performing their respective operations. While the program is described as being implemented as software, the present implementation may be implemented as a combination of hardware and software or hardware alone.

Although aspects of methods, systems, and articles of manufacture consistent with the present invention are depicted as being stored in memory, one having skill in the art will appreciate that these aspects may be stored on or read from other computer-readable media, such as secondary storage devices, like hard disks, floppy disks, and CD-ROM; a carrier wave received from a network such as the Internet; or other forms of ROM or RAM either currently known or later developed. Further, although specific components of an electrical tester and microcontroller have been described, one having skill in the art will appreciate that an electrical tester and microcontroller suitable for use with methods, systems, and articles of manufacture consistent with the present invention may contain additional or different components.

As shown in FIG. 3, the program executes in a loop until program execution is terminated, for example due to a low-battery or automatic power-off condition. One having skill in the art will appreciate that the individual tasks performed by the program, such as the automatic power-off task, can also execute continuously and independently of the other tasks. Further, the program instructions and their order of execution are merely illustrative. One having skill in the art will appreciate that the steps can be performed in an alternative order, and that additional or substitute processing steps can be executed.

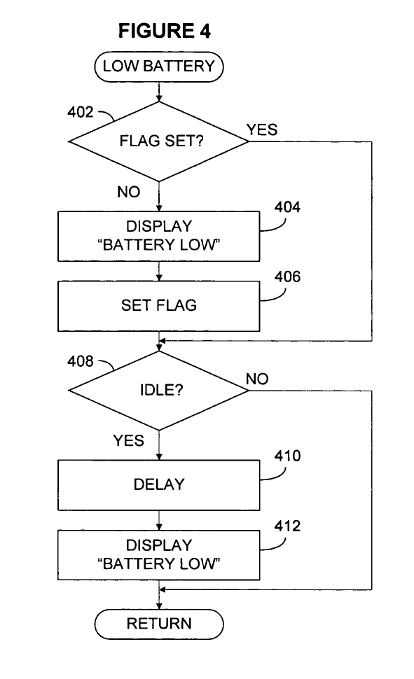

In the illustrative example, the program first determines whether there is a low-battery condition (step 302). This may be done by comparing the BATFP signal to a predetermined voltage value. If a low-battery condition is detected, the program provides an indication that there is a low-battery condition (step 304). FIG. 4 shows the processing of step 304 in more detail. In FIG. 4, the program determines whether a low-battery condition flag has been set by the program (step 402). When the electrical tester is first turned on and detects a low-battery condition, the flag is not set. Therefore, processing continues to step 404, and the program effects annunciation of the voice message “BATTERY LOW” once. To do so, the program retrieves macros for annunciating the words “BATTERY” and “LOW” from the EEPROM and annunciates the words. The steps performed by the program to annunciate words is described in more detail below with reference to annunciating measurement data. The program also turns on the low battery icon on the display. After annunciating the message, the program sets the low-battery flag to true (step 406).

Then, the program determines whether the electrical tester is idle (step 408). This is done, for example, by determining whether an inactivity timer is counting. If the electrical tester is idle, the program delays for a predetermined period of time, such as 5 seconds, (step 410) and then annunciates the voice message “BATTERY LOW” again (step 412). If the electrical tester was not idle in step 408 or after the voice message is annunciated in step 412, then the program returns to step 306 in FIG. 3. Therefore, when the electrical tester is idle, the program periodically annunciates a low-battery message until the electrical tester powers-off due to inactivity.

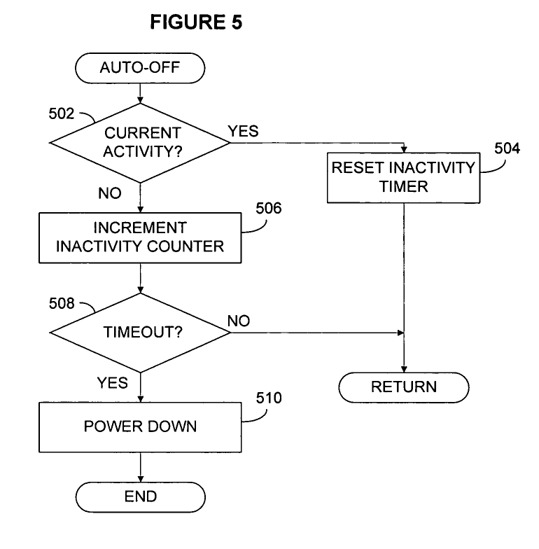

Returning to FIG. 3, the program then determines whether to invoke an automatic power-off due to inactivity (step 306). If the program determines that there is not current activity, then the program initiates automatic power-off (step 308). FIG. 5 depicts the processing of step 308 in more detail. In FIG. 5, the program determines whether there is inactivity (step 502). If there is current activity, then the program resets the inactivity timer to a value of “0” (step 504) and execution returns to step 310 of FIG. 3. If there is no current activity, then the program increments the inactivity timer (step 506). In the preferred embodiment, the preset amount of time is 10 seconds. If the inactivity timer has not yet reached 10 seconds (step 508), then execution returns to step 310. If the inactivity timer reaches 10 seconds, then the program switches off power by removing the signal to PWREN (step 510).

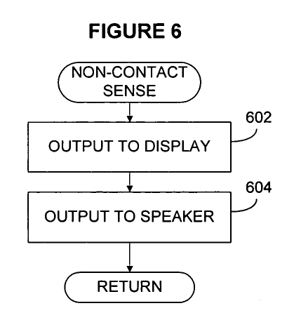

Referring back to FIG. 3, the program determines whether there is a signal inputted via the non-contact sensor (step 310). The program does this by checking the analog input voltage FIELD received from the field detector circuit. The analog input voltage is compared against a preset threshold, such as 100 volts, and if the voltage is above the threshold, then a signal has been detected. If a signal is identified in step 310, then the program presents an indication to the user (step 312). FIG. 6 depicts the processing of step 312 in more detail. In FIG. 6, the program outputs a message to the display device to indicate that a voltage has been detected (step 602). In the preferred embodiment, the program displays the message “AC” to indicate that an AC voltage has been detected. The program also generates a humming sound through the speaker to further notify the user of the detected signal (step 604). Further, the program can provide another type of indication, such as a voice annunciation. Program execution then returns to step 314 of FIG. 3.

The program then determines whether the LOUDER or SOFTER button has been depressed to adjust the speaker volume (step 314). The user can modify the volume of annunciated messages using the LOUDER and SOFTER buttons on the electrical tester. Volume settings are stored in the nonvolatile memory of the microcontroller so that the electrical tester will restore to the last-set volume level after a power-down and then a power-up. The microcontroller outputs signals on one or more of signal lines LEV0, LEV1 and LEV2 to the gain control circuit to adjust the volume (step 316). The gain control circuit provides eight volume levels approximately 8 dB apart.

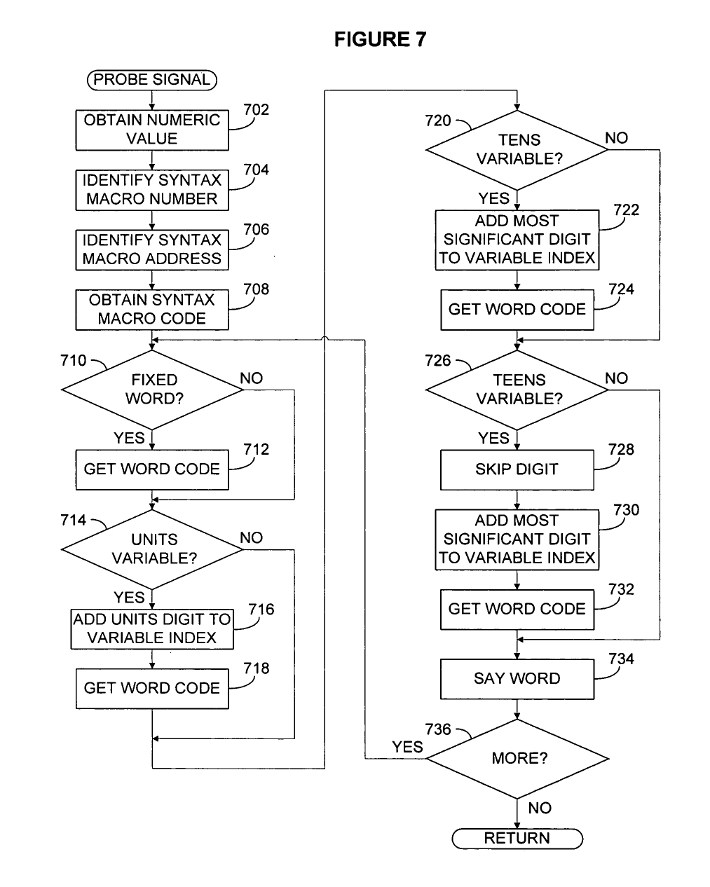

Then, the program determines whether a signal has been received via the first or second probe (step 314). If a probe signal is detected in step 314, then the program presents an indication to the user (step 316). FIG. 7 depicts the processing of step 316 in more detail. In the illustrative example, the electrical tester can annunciate the voltage readings described in Table 1.

TABLE 1

| Minimum | Maximum | Units | Significant Digits |
|---|---|---|---|
| 0.50 | 9.99 | VOLTS | 3 |
| 10.0 | 99.9 | VOLTS | 3 |
| 100 | 660 | VOLTS | 3 |

Further, the electrical tester can annunciate the resistance readings described in Table 2.

TABLE 2

| Minimum | Maximum | Units | Significant Digits |
|---|---|---|---|
| 0.0 | 9.9 | OHMS | 2 |
| 10.0 | 99.9 | OHMS | 3 |
| 100 | 999 | OHMS | 3 |

Combining the values in Tables 1 and 2, the electrical tester can annunciate the values described in Table 3.

TABLE 3

| | | | Significant | Number of |
|---|---|---|---|---|
| Minimum | Maximum | Units | Digits | Values |
| 0.0 | 9.9 | OHMS | 2 | 100 |
| 0.50 | 9.99 | VOLTS | 3 | 950 |
| 10.0 | 99.9 | VOLTS, OHMS | 3 | 900 |
| 100 | 999 | VOLTS, OHMS | 3 | 900 |

| | |
|---|---|
| Total | 2850 |

Thus, the illustrative electrical tester can annunciate 2850 numerical values, in addition to other words, such as “VOLT.” One having skill in the art will appreciate that numerical values may be annunciated with a different syntax depending on the spoken language. For example, the voltage 117 volts would be spoken with the syntax “ONE HUNDRED AND SEVENTEEN VOLTS” in English, but would be spoken with the syntax “HUNDRED SEVENTEEN VOLTS” in Italian. Therefore, electrical tester stores a macro list in the EEPROM that identifies a particular syntax for each of the 2850 numerical values. Starting at a predetermined memory location (which is the same for any language), the EEPROM holds 2850 one-byte values. Each value is a syntax macro number that tells the program how to construct the word elements to annunciate the relevant numerical value in the target language. An illustrative macro list is shown Table 4.

TABLE 4

| Entry Number | Numerical Value | Syntax Macro |
|---|---|---|
| 1 | 0.0 | 1 |
| 2 | 0.1 | 1 |
| 3 | 0.2 | 1 |
| . | . | . |
| . | . | . |
| . | . | . |
| 99 | 9.8 | 1 |
| 100 | 9.9 | 1 |
| 101 | 0.50 | 2 |
| 102 | 0.51 | 2 |
| . | . | . |
| . | . | . |
| . | . | . |
| 1049 | 9.98 | 2 |
| 1050 | 9.99 | 2 |
| 1051 | 10.0 | 3 |
| 1052 | 10.1 | 3 |
| . | . | . |
| . | . | . |
| . | . | . |
| 1060 | 10.9 | 3 |
| 1061 | 11.0 | 3 |
| 1062 | 11.1 | 3 |
| . | . | . |
| . | . | . |
| . | . | . |
| 1149 | 19.8 | 3 |
| 1150 | 19.9 | 3 |
| 1151 | 20.0 | 4 |
| 1152 | 20.1 | 4 |
| . | . | . |
| . | . | . |
| . | . | . |
| 1160 | 20.9 | 4 |
| 1161 | 21.0 | 5 |
| 1162 | 21.1 | 5 |
| . | . | . |
| . | . | . |
| . | . | . |
| 1949 | 99.8 | 5 |
| 1950 | 99.9 | 5 |
| 1951 | 100 | 6 |
| 1952 | 101 | 7 |
| 1953 | 102 | 7 |
| . | . | . |
| . | . | . |
| . | . | . |
| 1960 | 109 | 7 |
| 1961 | 110 | 8 |
| 1962 | 111 | 8 |
| 1963 | 112 | 8 |
| . | . | . |
| . | . | . |
| . | . | . |
| 1970 | 119 | 8 |
| 1971 | 120 | 9 |
| 1972 | 121 | 10 |
| 1973 | 122 | 10 |
| . | . | . |
| . | . | . |
| . | . | . |
| 1980 | 129 | 10 |
| 1981 | 130 | 9 |
| 1982 | 131 | 10 |
| . | . | . |
| . | . | . |
| . | . | . |
| 2050 | 199 | 10 |
| 2051 | 200 | 6 |
| 2052 | 201 | 7 |
| . | . | . |
| . | . | . |
| . | . | . |
| 2849 | 998 | 10 |
| 2850 | 999 | 10 |

Each syntax macro in Table 4 defines a specific syntax for putting together discrete words to make up a numerical message. The list in Table 4 is an illustrative syntax macro list for the English language. The number of macros and the meanings of the macros may vary for different languages. The meanings of the 10 English-language syntax macros from Table 4 are described in Table 5.

TABLE 5

| Syntax | | |
|---|---|---|
| Macro | Syntax Macro Description | Example English Numerical Value |
| 1 | UNITS, “POINT,” UNITS | NINE POINT NINE |
| 2 | UNITS, “POINT,” UNITS, | ZERO POINT FIVE ZERO |
| | UNITS | |
| 3 | TEENS, “POINT,” UNITS | ELEVEN POINT ZERO |
| 4 | TENS, “POINT,” UNITS | TWENTY POINT ZERO |
| 5 | TENS, UNITS, “POINT,” | TWENTY-ONE POINT ZERO |
| | UNITS | |
| 6 | UNITS, “HUNDRED” | ONE HUNDRED |
| 7 | UNITS, “HUNDRED,” | ONE HUNDRED AND ONE |
| | “AND,” UNITS | |
| 8 | UNITS, “HUNDRED,” | ONE HUNDRED AND ELEVEN |
| | “AND,” TEENS | |
| 9 | UNITS, “HUNDRED,” | ONE HUNDRED AND TWENTY |
| | “AND,” TENS | |
| 10 | UNITS, “HUNDRED,” | ONE HUNDRED AND |
| | “AND,” TENS, UNITS | TWENTY-ONE |

Therefore, the program identifies the numeric value of the measured data (step 702). The measure data has a numeric value, for example, of 119 volts. Then, the program identifies the syntax macro number corresponding to the numeric value (step 704). This can be done by looking up the relevant syntax macro number from Table 4. For example, for the numeric value “119,” the program determines that the syntax macro number is “8.”

Once the program identifies the syntax macro for a particular numerical reading, the program vectors into a syntax macro address table (step 706). The syntax macro address table stars at a predetermined location within the EEPROM, such as location 4,096 (decimal). Space may be allocated for up to 256 syntax macros. Each entry in the table is a two-byte address that tells the program where it can find the first byte of the coding for that particular syntax macro. Table 6 shows illustrative addresses for the English-language macros. For example, the program would identify that syntax macro 8 can be found at EEPROM address 5025.

TABLE 6

| Syntax Macro | EEPROM Address |
|---|---|
| 1 | 4096 |
| 2 | 5000 |
| 3 | 5005 |
| 4 | 5009 |
| 5 | 5013 |
| 6 | 5017 |
| 7 | 5020 |
| 8 | 5025 |
| 9 | 5030 |
| 10 | 5035 |

After identifying where a syntax macro is located in memory, the program retrieves the syntax macro code (step 708). A syntax macro coding table, which includes the syntax macro codes, contains instructions for building-up the phrases for each specific syntax macro. An illustrative syntax macro coding table is shown in Table 7. The first byte is a length indicator that identifies how many bytes follow. In Table 7, “V” and “W” mnemonic codes to indicate variable and words, respectively, whereas in the actual EEPROM, numeric codes would appear (as described further below). The syntax macros are not limited to just five values, as shown in Table 7, but five values suffices for English.

TABLE 7

| SYNTAX | LENGTH | VALUE | VALUE | VALUE | VALUE | VALUE |
|---|---|---|---|---|---|---|
| MACRO | BYTE | #1 | #2 | #3 | #4 | #5 |
| 1 | 3 | V(U) | W(34) | V(U) | — | — |
| 2 | 4 | V(U) | W(34) | V(U) | V(U) | — |
| 3 | 3 | V(TN) | W(34) | V(U) | — | — |
| 4 | 3 | V(T) | W(34) | V(U) | — | — |
| 5 | 4 | V(T) | V(U) | W(34) | V(U) | — |
| 6 | 2 | V(U) | W(28) | — | — | — |
| 7 | 4 | V(U) | W(28) | W(33) | V(U) | — |
| 8 | 4 | V(U) | W(28) | W(33) | V(T) | — |
| 9 | 4 | V(U) | W(28) | W(33) | V(TN) | — |
| 10 | 5 | V(U) | W(28) | W(33) | V(T) | V(U) |

Further, for each language, a word list includes spoken words that can be used in combination to generate a spoken message to be annunciated by the electrical tester. An illustrative word list is shown in Table 8.

TABLE 8

| Word Number | Word |
|---|---|
| 0 | ZERO |
| 1 | ONE |
| 2 | TWO |
| 3 | THREE |
| 4 | FOUR |
| 5 | FIVE |
| 6 | SIX |
| 7 | SEVEN |
| 8 | EIGHT |
| 9 | NINE |
| 10 | TEN |
| 11 | ELEVEN |
| 12 | TWELVE |
| 13 | THIRTEEN |
| 14 | FOURTEEN |
| 15 | FIFTEEN |
| 16 | SIXTEEN |
| 17 | SEVENTEEN |
| 18 | EIGHTEEN |
| 19 | NINETEEN |
| 20 | TWENTY |
| 21 | THIRTY |
| 22 | FORTY |
| 23 | FIFTY |
| 24 | SIXTY |
| 25 | SEVENTY |
| 26 | EIGHTY |
| 27 | NINETY |
| 28 | HUNDRED |
| 29 | OVER |
| 30 | BATTERY |
| 31 | A |
| 32 | D |
| 33 | AND |
| 34 | POINT |
| 35 | VOLTS |
| 36 | C |
| 37 | LOW |
| 38 | OHMS |

The code for each word (i.e., the code that is stored in the syntax macro coding table of Table 7) is one of the word numbers from Table 8. Under this coding scheme, the illustrative EEPROM may store up to 128 words (word codes 0 through 127). In the illustrative example, however, word codes 0 through 28 are defined for English. The remaining codes 128 through 255 can be reserved for variables, which are described in more detail below.

The program traverses the syntax macro code from left to right to process each value in the syntax macro code. For example, for the syntax macro 8, the syntax macro code's first value is a unit variable V(U). If the current value is a fixed word, such as “BATTERY LOW,” the program vectors to word's address in a word address table (step 710). An illustrative English-language word address table is shown in Table 9 and obtains the word code at that address (step 712). Each row in the word address table corresponds to one of the 39 words identified in the English-language word list of Table 8. Further, each entry in the word address table contains four bytes. The first two bytes comprise a 16-bit address that tells the program wherein the EEPROM it can find the first byte of the compressed digitized voice data for the indexed word. The next two bytes comprise a length indicator that informs the program the length of the word, measured in ticks of the audio sample clock.

TABLE 9

| Word Number | EEPROM Address | Sample Length |
|---|---|---|
| 0 | 6144 | 4 |
| 1 | TBD | 4 |
| 2 | TBD | 4 |
| . | . | . |
| . | . | . |
| . | . | . |
| 37 | TBD | 4 |
| 38 | TBD | 4 |

As noted above with reference to the word codes of Table 7, the “V” and “W” mnemonic codes indicate variables and words, respectively, whereas in the EEPROM, numeric variable codes would appear. A variable stored in a syntax macro code is used to map the value of a certain numeric digit to the appropriate value of a numeric word. In the illustrative example, variable codes may take on values from 128 to 255. As noted above, values stored in the syntax macro coding table that are in the range of 0 to 128 represent fixed words. Examples of the variables used to support the English language are shown in Table 10.

TABLE 10

| Variable | Variable | | Variable |
|---|---|---|---|
| Mnemonic | Description | Values of Spoken Word | Code |
| V(U) | UNITS | 0, 1, 2, 3, 4, 5, 6, 7, 8, 9 | 128 |
| V(TN) | TEENS | 10, 11, 12, 13, 14, 15, 16, 17, 18, | 129 |
| | | 19 | |
| V(T) | TENS | 20, 30, 40, 50, 60, 70, 80, 90 | 130 |

When the program finds a value in syntax macro coding table that is in the range of 128 to 255, it recognizes a variable code rather than the code for a fixed word. Then, the program vectors into a variable code table to obtain digit skip information and a variable index. The variable code table starts at a predetermined location within the EEPROM, such as at location 7,168 (decimal). An illustrative variable code table is shown in Table 11.

TABLE 11

| Variable Code | Variable Description | Digit Skip | Variable Index |
|---|---|---|---|
| 128 | UNITS | 0 | 0 |
| 129 | TEENS | 1 | 10 |
| 130 | TENS | 0 | 18 |

Each entry in the variable code table (e.g., Table 11) contains two bytes. The first byte is a digit skip code. The second byte is a variable index. The program develops measurement values of two or three decimal digits of resolution. It starts speaking with the most significant digit. If the second digit is significant, it speaks that digit. If the third digit is significant, it speaks that digit. The number of digits to speak for a given numeric variable is determined by the syntax macro for that numeric variable. When non-zero, the digit skip code instructs the program to skip a significant digit, moving to the right. The variable index provides the value to be added to the digit currently being annunciated, to produce the appropriate spoken word.

If the program determines that the syntax macro code's value is a units variable (i.e., variable code 128) (step 714), then the program adds the units digit to the variable index (716). For example, if the numerical value is 119 and the current value is the first 1, then the program adds the value 1 to the variable index 0. This provides the word code for the word to be annunciated. Thus, the program retrieves the word code from the EEPROM for the word code 1, which is “one” (step 718).

If the program determines that the syntax macro code's value is a tens variable (i.e., variable code 130) (step 720), then the program adds the most significant digit to the variable index (722). For example, if the numerical value is 20.0 and the current value is the 2, then the program adds the value 2 to the variable index 18. This provides the word code for the word to be annunciated. Thus, the program retrieves the word code from the EEPROM for the word code 20, which is “twenty” (step 724).

If the program determines that the syntax macro code's value is a teens variable (i.e., variable code 129) (step 726), then the program skips a digit, because the teens variable is associated with a digit skip of 1 (step 728). The program then adds the most significant digit to the variable index (730). For example, if the numerical value is 119, the program speaks the “one,” then “hundred,” then “and,” as defined by syntax macro 9. When ready to speak the second most significant digit, which is associated with a teens variable, the program skips the second most significant digit, the second 1, moving to the least significant digit 9. The program adds this digit value, 9, to the variable index, 10, to produce 19 (step 730). This provides the word code for the word to be annunciated. Thus, the program retrieves the word code from the EEPROM for the word code 19, which is “nineteen” (step 732).

After obtaining the word code for the word to be annunciated, the program annunciates the word (step 734). If there are additional values or digits to annunciate, then execution returns to step 710.

Depending on the spoken language, the numerical value may be spoken before or after the parameter name (e.g., “volts”). To support this functionality, the program may look-up a parameter position value, which identifies whether the parameter name should be spoken prior to speaking the numerical value.

In an embodiment, the electrical tester can annunciate a measured signal value with sounds other than voice sounds. For example, the value 119 volts can be represented by one or more tones instead of the spoken words “119 volts.” In that example, a first tone can identify the value 100 and one or more other tones can identify the value 19. Thus, the electrical tester can be used by a person who may not be familiar with one of the available languages, but who can understand the tonal annunciations.

Therefore, unlike conventional electrical testers, which merely provide a read-out display or a vibration, methods and systems consistent with the present invention provide an electrical tester having a voice annunciator. Thus, when there is a low-light condition or if a user cannot see the electrical tester's display device, the user can still hear the measured value via the electrical tester's voice annunciation.

Further, the electrical tester can beneficially support different languages by changing the tables in the EEPROM, without having to modify the program in the microcontroller. Also, the electrical tester can be provided with multiple EEPROMs, each supporting a different language. Thus, a user that desires to change the electrical tester's language can effect the change by changing out the EEPROM.

The foregoing description of an implementation of the invention has been presented for purposes of illustration and description. It is not exhaustive and does not limit the invention to the precise form disclosed. Modifications and variations are possible in light of the above teachings or may be acquired from practicing the invention. For example, the described implementation includes software but the present implementation may be implemented as a combination of hardware and software or hardware alone. Further, the illustrative processing steps performed by the program can be executed in an different order than described above, and additional processing steps can be incorporated. The invention may be implemented with both object-oriented and non-object-oriented programming systems. The scope of the invention is defined by the claims and their equivalents.

When introducing elements of the present invention or the preferred embodiment(s) thereof the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description or shown in the accompanying drawings shall be interpreted as illustrative and not in a limiting sense

1. A method in a handheld electrical tester having a program, the method comprising the steps of:
measuring a measurement data having a value;
determining one or more spoken words corresponding to the measured data's value; and
annunciating the one or more spoken words.

2. The method of claim 1, wherein the measurement data is voltage data.

3. The method of claim 1, wherein the measurement data is conductivity data.

4. The method of claim 1, wherein the measurement data is current data.

5. The method of claim 1, further comprising the step of displaying the measurement data's value on a display.

6. The method of claim 1, wherein the step of determining the one or more spoken words comprises using one or more language syntax rules to choose the one or more spoken words.

7. A handheld electrical tester comprising:
a memory having a program that measures a measured data having a value, determines one or more spoken words corresponding to the measured data's value, and annunciates the one or more spoken words; and
a processor that runs the program.

8. A handheld electrical tester comprising:
a sensor that measures a voltage potential;
a processor that determines one or more spoken words corresponding to a value of the measured voltage potential; and
a speaker that annunciates the one or more spoken words.

9. The handheld electrical tester of claim 8 further comprising:
a display for displaying the value of the measured voltage potential.

10. The handheld electrical tester of claim 8, wherein the sensor can measure a conductivity, and wherein the processor can determine one or more spoken words corresponding to a value of the measured conductivity and the speaker can annunciate the one or more spoken words corresponding to a value of the measured conductivity.

11. The handheld electrical tester of claim 10, wherein the processor can automatically switch from a mode to measure voltage potential to a mode to measure conductivity.

12. The handheld electrical tester of claim 8 further comprising:
a secondary memory having stored thereon language syntax rules and the one or more spoken words, the processor determining the one or more spoken words using the language syntax rules.

13. The handheld electrical tester of claim 12, wherein the language syntax rules and the one or more spoken words stored in the secondary memory can be replace with replacement language syntax rules and one or more replacement spoken words without modifying processing steps performed by the processor.

14. The handheld electrical tester of claim 12, wherein the secondary memory can be replaced with a replacement secondary memory having replacement language syntax rules and one or more replacement spoken words stored thereon.

15. A handheld electrical tester comprising:
a memory having a program that measures a measured data having a value, determines one or more audible sounds corresponding to the measured data's value, and annunciates the one or more audible sounds; and
a processor that runs the program.
